(19) United States
(12) Patent Application Publication
(10) Pub. No.: US 2007/0096024 A1
(43) Pub. Date: May 3, 2007

(54) IMAGE-CAPTURING APPARATUS

(75) Inventors: Hiroaki Furuya, Suwa-shi (JP); Kunihiko Kanai, Suwa-shi (JP)

Correspondence Address: Pamela R. Crocker;Patent Legal Staff, Eastman Kodak Company, 343 State Street, Rochester, NY, 14650-2201, US

(73) Assignees: Hiroaki Furuya; Kunihiko Kanai

(21) Appl. No.: 11/464,914

(22) Filed: Aug. 16, 2006

(30) Foreign Application Priority Data
Oct. 27, 2005 (JP) 2005-313336

(51) Int. Cl. H01L 25/00

(52) U.S. Cl. 250/332

(57) ABSTRACT

A digital camera automatically determines a scene for image capturing. A temperature sensor detects the temperature of a field, and a temperature-based information characteristic extraction circuit classifies the temperature into any of “high temperature,” “body temperature,” and “low temperature” categories. A scene determination circuit determines a scene by combination of temperature characteristics with movements, a hue, saturation, luminance, and the like, of an image detected by an image characteristic extraction circuit. For instance, when a lower portion of the screen has a low color temperature and a low saturation level, the scene is determined to be snow scene. According to the determined scene, a CPU controls exposure, shutter speed, the quantity of strobe light, and the like.

### CROSS REFERENCE TO RELATED APPLICATIONS

This application claims priority to Japanese Patent Application No. 2005-313336 filed on Oct. 27, 2005, which is incorporated herein by reference in its entirety.

### FIELD OF THE INVENTION

The present invention relates to an image-capturing apparatus, and more particularly to automatic determination of a scene for image capturing (hereinafter called a “photographic scene”).

### BACKGROUND OF THE INVENTION

An image-capturing apparatus, such as a digital camera, or the like, has hitherto been equipped with a mode selection button which enables selection of macroscopic photographing or a photographic scene (or a photographing mode) such as a portrait, a sports scene, a landscape, and the like. The user manually operates the mode selection button according to a subject to be photographed, to thus make settings. The digital camera controls exposure, white balance, and shutter speed according to the photographic scene (or the photographing mode) set by the user, thereby capturing an image of the subject.

In view that the user must perform intricate operations to manually select a photographic scene, there have been proposed techniques by means of which a digital camera automatically determines a photographic scene to a certain extent to thus capture the thus-determined photographic scene.

For instance, Japanese Patent Laid-Open Publication No. 2003-344891 describes a technique for ascertaining whether or not a subject includes a face and automatically setting a photographing mode of a camera according to a result of ascertainment. When a human face has been detected and a scaling factor for photographing is a given value or less, the photographing mode is set to a normal mode. When the scaling factor is greater than the given value, the photographing mode is set to a portrait mode. When the human face is not detected, a distance to the subject is a given value or greater, and it is nighttime, the photographing mode is set to a night view mode. If it is not nighttime, the photographing mode is set to a landscape mode or the like.

Japanese Patent Laid-Open Publication No. Hei-8-136971 describes that a camera is equipped with an infrared sensor; that an area of body temperature (hereinafter simply called a “body-temperature area”) showing the temperature of a body is extracted; and that exposure and a focal point are determined in accordance with a photometric value acquired in the body-temperature range and a measured distance to the body-temperature area.

As mentioned above, a technique for automatically determining a photographic scene on the basis of some pieces of information has heretofore been available. However, it is hard to say that various photographic scenes can be determined without fail. For example, even when a human face is not detected, a distance to the subject is a given distance or greater, and it is not nighttime, an actual photographic scene is a scene of a beach or a scene of snowy mountains. If these scenes are indiscriminately determined to belong to a landscape mode, acquisition of a high-quality image cannot be expected.

Japanese Patent Laid-Open Publication No. Hei-8-136971 describes acquisition of temperature information by means of the infrared sensor. However, this technique is confined to detection of the body-temperature area, and determination of a scene is not taken into account.

The present invention provides an image-capturing apparatus which enables enhanced accuracy of determination of a scene and easy acquisition of a higher-quality image.

### SUMMARY OF THE INVENTION

The present invention provides an image-capturing apparatus comprising:

temperature detection means for detecting a temperature of a field;

image acquisition means for acquiring an image signal pertaining to the field;

image-processing means for detecting image characteristic information, such as a hue, saturation, luminance, a distance, movements, and the like, from the image signal obtained by the image acquisition means; and

determination means for determining which one of a plurality of photographic scenes corresponds to the field, on the basis of a combination of the temperature information about the field detected by the temperature detection means and the image characteristic information detected by the image-processing means.

In the present invention, a photographic scene can be automatically determined with high accuracy by means of a combination of the temperature of a field with image characteristic information, such as movements, a hue, saturation, luminance, and the like, of an image. Consequently, photographing conditions can be adjusted according to a scene to be determined. The user can acquire a high-quality image according to a scene by means of merely orienting the image-capturing apparatus to the field and capturing an image.

The invention will be more clearly comprehended by reference to the embodiments provided below. However, the scope of the invention is not limited to the embodiments.

### BRIEF DESCRIPTION OF THE DRAWINGS

Preferred embodiments of the present invention will be described in detail with reference to the following figures, wherein:

FIG. 1 is a block diagram of a digital camera according to a first embodiment of the present invention;

FIG. 2 is an overall processing flowchart of the embodiment;

FIG. 3 is a detailed flowchart of temperature characteristic detection processing in the embodiment;

FIG. 4A is a descriptive view of temperature characteristics of a beach;

FIG. 4B is a descriptive view of temperature characteristics of a snowy mountain;

FIG. 5 is a descriptive view of categories (patterns) used in processing for detecting characteristics of an image;

FIG. 6 is a detailed flowchart of processing for determining a scene (a photographing mode);

FIG. 7 is a descriptive view of a table used in processing for determining a scene;

FIG. 8 is a descriptive view of a table used in photographic control based on a determined scene;

FIG. 9 is a descriptive view of a category used for detecting temperature characteristics in another embodiment;

FIG. 10 is a descriptive view of a table used in processing for determining a scene in another embodiment;

FIG. 11 is a descriptive view of a table used in photographic control based on a determined scene; and

FIG. 12 is a descriptive view of temperature characteristic detection in yet another embodiment, showing a descriptive view of temperature characteristic detection achieved when only a body temperature is taken as an object.

### DETAILED DESCRIPTION OF THE PREFERRED EMBODIMENTS

### First Embodiment

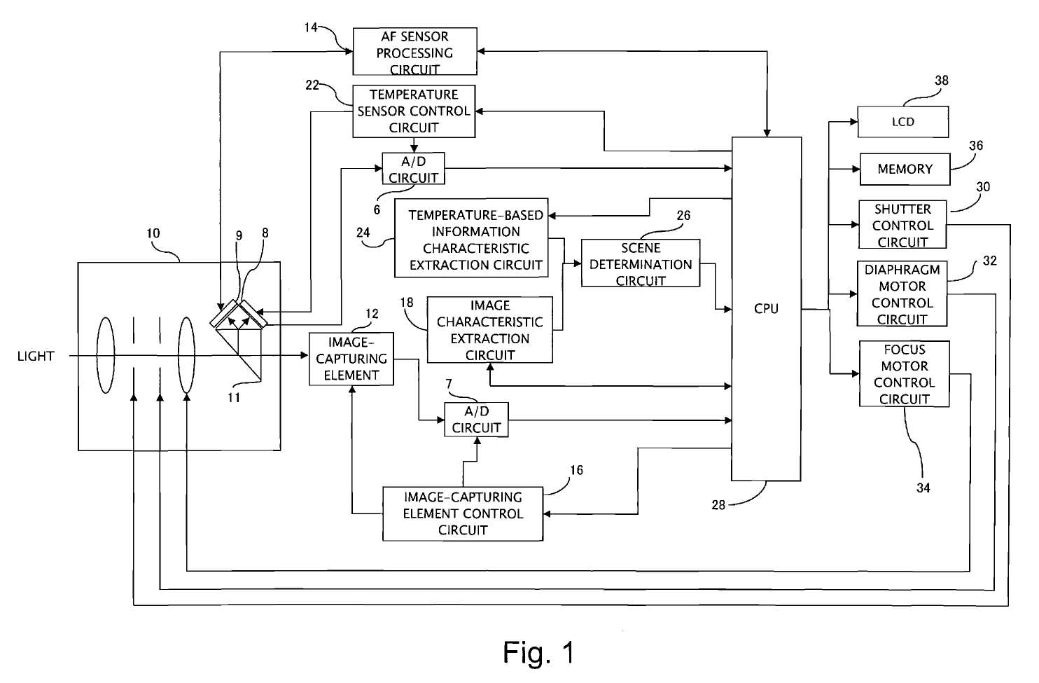

FIG. 1 shows a block diagram of a digital camera according to a first embodiment of the present invention. An optical system 10 including a group of lenses, a shutter, a diaphragm, and the like, gathers light of a field and guides the thus-gathered light to an image-capturing element 12. Opening and closing of the shutter is controlled by a shutter control circuit 30, and a diaphragm is controlled by a diaphragm motor control circuit 32. A focus lens of the group of lenses is controlled by a focus motor control circuit 34.

The image-capturing element 12 converts light of the field into an electrical signal, to thus generate an image signal. The image-capturing element 12 includes a known Bayer-arrangement color filter. The image signal is converted into a digital signal by means of an analog-to-digital circuit 7, and the digital signal is supplied to a CPU 28. The digital signal is further supplied from the CPU 28 to an image characteristic extraction circuit 18. The image signal supplied to the CPU 28 is subjected to image processing such as white balance adjustment, edge enhancement processing, and the like. The thus-processed image signal is displayed on a color LCD 38. Further, the processed image is converted into a JPEG format or a RAW format in response to operation of a release button, and the thus-converted image is stored as a captured image externally or in built-in memory 36. Driving of the image-capturing element 12 is controlled by an image-capturing element drive circuit 16.

In the meantime, the light having entered the optical system 10 is bifurcated by a half mirror 11, and one of the thus-bifurcated beams enters an AF (autofocus) sensor 9. A sensor signal output by the AF sensor 9 is processed by an A/F sensor processing circuit 14, to thus compute a distance to the subject by means of, e.g., a phase detection method. The subject distance information is supplied to the CPU 28. The other of the beams bifurcated by the half mirror 11 is converted into an electrical signal by means of a temperature sensor 8, and the electrical signal is converted into a digital signal by means of an analog-to-digital circuit 6. The thus-converted digital signal is supplied to the CPU 28. The temperature sensor 8 is, e.g., a radiation thermometer. The radiation thermometer utilizes the phenomenon that all objects radiate heat in the form of electromagnetic waves. A temperature can be detected from a wavelength distribution of thermal radiation energy and the intensity of each of wavelengths. In accordance with a command from the CPU 28, the temperature sensor 8 is controlled by a temperature sensor control circuit 22, and the detected temperature of the field is supplied from the CPU 28 to a temperature-based information characteristic extraction circuit 24. Alternatively, the temperature of the field may also be detected by means of a sensor for detecting the temperature of a field other than the temperature sensor 8; e.g., a two-dimensional image sensor for detecting infrared radiation. A technique for detecting the temperature distribution of a two-dimensional image has already been known as a thermography technique, an infrared thermography technique, or the like. All of the thus-detected temperatures are supplied to the temperature-based information characteristic extraction circuit 24 by way of the CPU 28.

Temperature data pertaining to the field, which have been detected by the temperature sensor 8 or another sensor, are input to the temperature-based information characteristic extraction circuit 24, where the characteristic of the temperature distribution of the field is detected. Specifically, the temperature-based information characteristic extraction circuit 24 divides a two-dimensional field image into a plurality of blocks, and classifies temperature distributions of the respective blocks into any of a plurality of predetermined temperature categories, thereby characterizing the temperature distributions. The temperature categories are arbitrary. However, the temperature categories can be classified into three categories; e.g., “body temperature,” “high temperature,” and “low temperature.” Temperatures detected by the temperature sensor 8, or the like, are classified into any of the three categories. The body temperature is an example human temperature. A magnitude correlation among the temperatures is defined as high temperature>body temperature>low temperature. A classification method includes, for example, setting two threshold temperatures T1, T2 (T1>T2); computing a typical temperature of each of the blocks from the temperatures detected by the temperature sensor 8 or the like (a typical temperature is computed by means of averaging, e.g., temperature distributions of the respective blocks); and comparing the typical temperature with the threshold temperatures T1, T2. When the typical temperature T exhibits a relationship of T>T1, the block is classified into the “high temperature” category. When the typical temperature T exhibits a relationship of T1>T>T2, the block is classified into the “body temperature” category. When the typical temperature T exhibits a relationship of T<T2, the block is classified into the “low temperature” category. The result of classification is supplied to a scene determination circuit 26.

The image characteristic extraction circuit 18 processes the field image input by the CPU 28, to thus detect image characteristic information such as a hue, saturation, a luminance, movements, and the like. The subject distance detected by the AF sensor control section 14 is input to the image characteristic extraction circuit 18, and the detected values are classified into any of a plurality of categories. For instance, a hue of the image characteristic information is classified as “red,” “blue,” or the like, in accordance with a color histogram. The saturation of the image characteristic information is classified into any of “low saturation” and “high saturation” categories. The distance of the image characteristic information is classified into any one of a “near distance,” a “middle distance,” a “long distance,” or the like. An image is divided into a plurality of blocks, and classification is carried out on a per-block basis. The blocks subjected to the image characteristic extraction circuit 18 may be identical with or different from the blocks subjected to the temperature-based information characteristic extraction circuit 24. For instance, the blocks subjected to the image characteristic extraction circuit 18 are broken into pieces which are smaller than the blocks subjected to the temperature-based information characteristic extraction circuit 24. The result of classification is supplied to the scene determination section 26.

The result of classification output from the temperature-based information characteristic extraction circuit 24 and the result of classification output from the image characteristic extraction circuit 18 are input to the scene determination circuit 26, whereby a scene of the field is determined on the basis of these results. The scene to be determined in the present embodiment includes a portrait (Portrait) scene, a sports (Sports) scene, a beach (Beach) scene, a snow (Snow) scene, and a landscape (Landscape) scene. The thus-determined scene becomes a photographing mode of the digital camera. The result of determination of a scene is supplied to the CPU 28.

The CPU 28 controls individual sections of the digital camera; supplies a control signal to at least any one of the shutter control circuit 30, the diaphragm motor control circuit 32, and the focus motor control circuit 34 according to, especially, a determined scene; and controls exposure, a shutter speed, and white balance, which are photographic conditions employed during photographing action. The CPU 28 controls edge processing of a captured image to thus determine whether the sharpness of the captured image is set to hard (an enhanced edge) or soft (a smooth edge). More specifically, a program which specifies control specifics for respective determined scenes has been stored as a firmware in ROM in advance, and control responsive to the determined scene is performed in accordance with the firmware. For instance, when the determined scene is a beach (Beach), the CPU 28 supplies a control signal to the diaphragm motor control circuit 32 to thereby control exposure in such a way that exposure, which is slightly higher than appropriate exposure, is achieved. When the determined scene is a landscape (Landscape), the CPU 28 supplies a control signal to the diaphragm motor control circuit 32 to thus control exposure in order to capture an image at the highest possible diaphragm setting.

Each of the temperature-based information characteristic extraction circuit 24, the image characteristic extraction circuit 18, and the scene determination circuit 26, all of which are shown in FIG. 1, is formed from a microprocessor. However, some of these circuits may be formed from a common microprocessor.

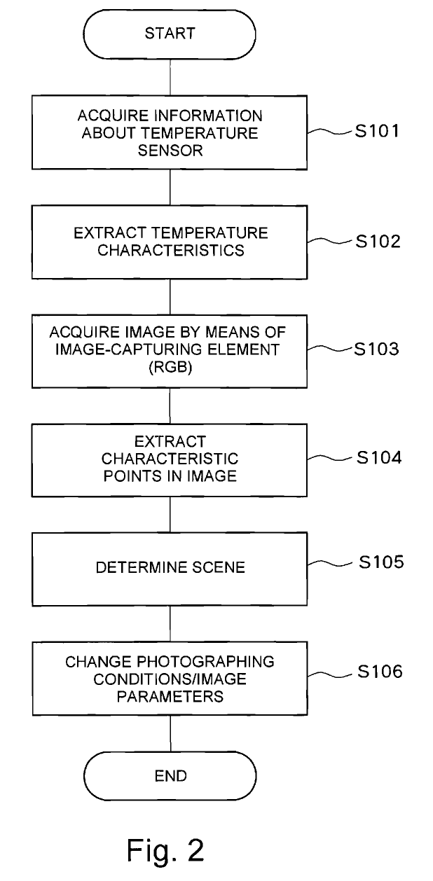

FIG. 2 shows an overall processing flowchart of the present embodiment. When the power of the digital camera is activated, the temperature sensor 8 acquires temperature information about the field (S101), and the temperature-based information characteristic extraction circuit 24 detects the characteristic of a temperature (S102). Namely, the temperature-based information characteristic extraction circuit 24 classifies the temperatures of the respective blocks of the two-dimensional image of the field into any of a plurality of temperature categories, to thus detect the characteristic of the temperature of the field. Next, the image of the field is captured by the image-capturing element 12 (S103), and the image characteristic extraction circuit 18 detects a characteristic of the image (S104). The image characteristic extraction circuit 18 classifies the hue, the saturation, the movements, the distance, and the like, of the two-dimensional image pertaining to the field into any of the plurality of categories, thereby detecting the characteristic of the image. After detection of the characteristic of the temperature and the characteristic of the image, the scene determination circuit 26 determines a photographic scene of the field (S105). Finally, the CPU 28 effects image-capturing operation by means of changing the photographic conditions and image parameters in accordance with the determined scene (S106).

Respective processing operations will be described in detail hereunder.

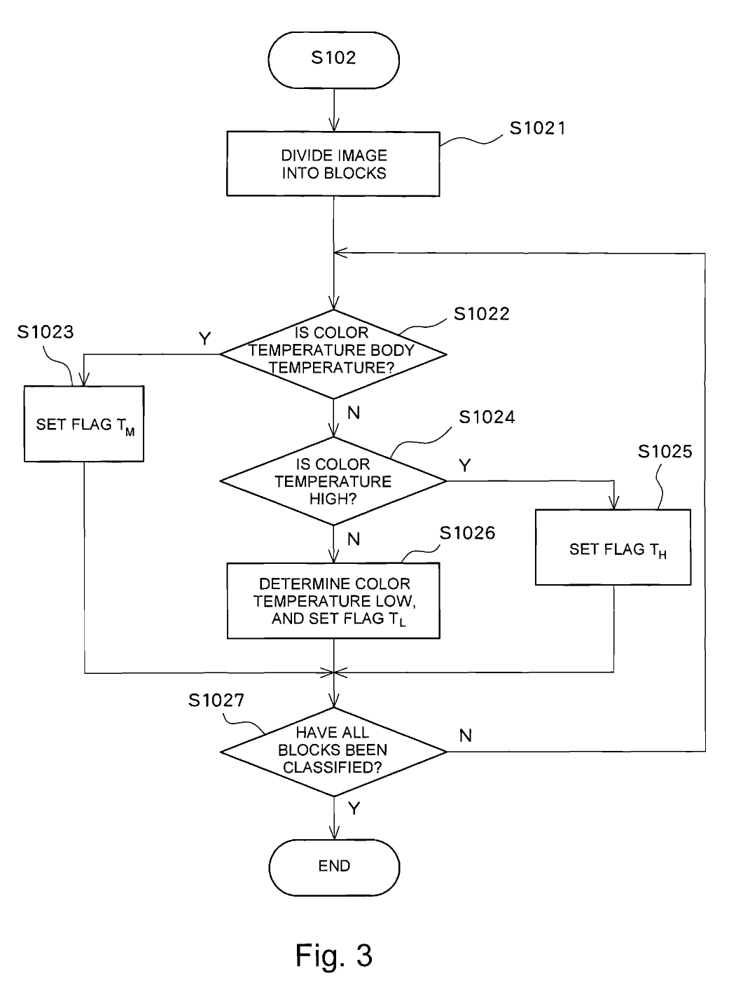

FIG. 3 is a detailed flowchart of processing pertaining to S102 shown in FIG. 2; namely, processing for extracting temperature characteristics of a field. The temperature-based information characteristic extraction circuit 24 divides the range of a field image, which is an object to be detected by the temperature sensor 8, into a plurality of blocks (S1021). For instance, the range of the field image is divided into six blocks. Next, the typical temperature is computed on a per-block basis, and a determination is made as to whether or not the thus-computed typical temperature corresponds to the “body temperature” (S1022). This determination is performed by means of comparing the typical temperature with the threshold temperatures T1, T2 as mentioned above. When the typical temperature is determined to be “body temperature,” a flag TM showing “body temperature” is set in that block (S1023). Meanwhile, when the typical temperature is not “body temperature,” a determination is then made as to whether or not the typical temperature corresponds to “high temperature” (S1024). This determination is also made by means of comparing the typical temperature with the threshold temperatures T1, T2. When the typical temperature corresponds to “high temperature,” a flag TH showing “high temperature” is set in that block (S1025). When the typical temperature corresponds to neither “body temperature” nor “high temperature,” a flag TL showing “low temperature” is set in the block (S1026). All of the blocks are repeatedly subjected to the above-mentioned classification processing (S1027).

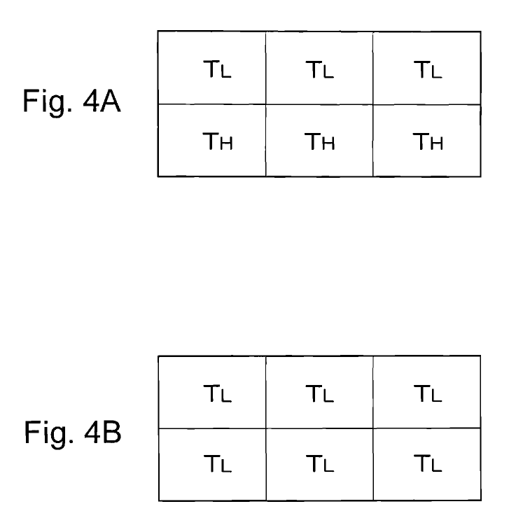

FIGS. 4A and 4B show results acquired as a result of different fields being subjected to temperature characteristic extraction. FIG. 4A shows a result acquired when the field is a beach, and FIG. 4B shows a result acquired when the field is a snowy mountain. White sands of a beach and snow surfaces of a snowy mountain look analogous in terms of a hue and saturation when viewed with the human eye, but may show a clear difference in temperature. As shown in FIG. 4A, an upper portion of a screen of the beach is classified into the category TL, but a lower portion of the same is classified into the category TH. As shown in FIG. 4B, an upper portion and a lower portion, both of which pertain to a screen of the snowy mountain, are classified into the category TL. For these reasons, the white sands of the beach and the white snow surfaces of the snowy mountain can be discriminated from each other as a result of use of the temperature characteristics.

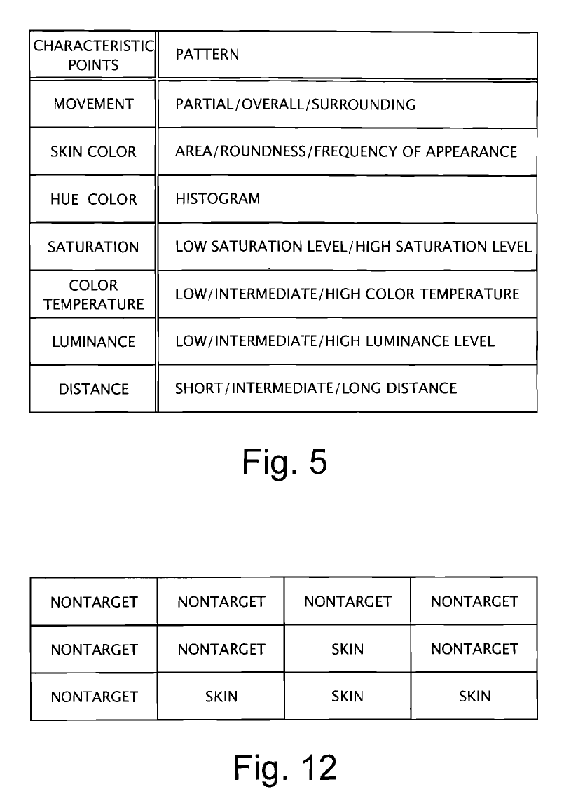

FIG. 5 shows categories used in processing pertaining to S104 shown in FIG. 2; namely, processing for extracting characteristics of an image. The image characteristic extraction circuit 18 processes the image signal obtained by the image-capturing element 12 to thus detect movements, a hue, saturation, luminance, and the like; and classifies the detected movements into any of categories such as those shown in FIG. 5. Movements are classified into any of “partial,” “overall,” and “surrounding” categories. Movements can be detected by means of computing a difference between frames which differ from each other in terms of time. More specifically, the essential requirement is to move a frame of a block F(n-1), which is a precedent block in terms of time, vertically and horizontally within a specified width; and to detect, as a motion vector, a direction (dx, dy) which realizes a minimum total difference between the frame of the precedent block and a frame F(n) of a block subsequent in terms of time; i.e.,

$$D = \sum \sum \vert F ( n ) ( Xi , Yi ) - F ( n - 1 ) ( X ) i + dx , Yi + dy \vert .$$

Although the amount and direction of movement are detected by means of a motion vector, in the present embodiment attention is paid particularly to the amount of movement and the position of the motion vector. When the thus-detected movement is present in only a portion of the field, the movement is classified into the “partial” category. When the movement is present in the entire field, the movement is classified into the “overall” category. When the movement is present in only the surroundings of the field, the movement is classified into the “surrounding” category. A skin color is included in hue, but in the present embodiment is assumed to be detected separately from hue. The thus-detected skin color is characterized by “area,” “roundness,” and “frequency of appearance.” Here, the term “area” signifies an area occupied by pixels in a detected single skin color region. The term “roundness” signifies the degree of similarity achieved when an occupied area in the detected single skin color region is analogous to a circle. These terms may be expressed by numerals or geometrical categories.

The area is classified into “large,” “middle,” and “small” categories. The roundness is classified into “circle,” “oval,” and “rectangular” categories. The frequency of appearance is classified into “high,” “intermediate,” and “low” categories. Hue is classified by a color histogram. Saturation is classified into “low saturation” and “high saturation.” A color temperature is classified into “low,” “intermediate,” and “high” categories. For instance, a color temperature of 400 klv or less is classified into the “low” category. A color temperature from 4000 klv to 6500 klv is classified into the “intermediate” category. A color temperature of 6500 klv or more is classified into the “high” category. Luminance is classified into “low,” “intermediate,” and “high” categories. For instance, a luminance of LV8 or less is classified into the “low” category. A luminance of LV8 to LV12 is classified into the “middle” category. A luminance of LV12 or more is classified into the “high” category. A distance to the subject is classified into “short,” “middle,” and “long.” For instance, a distance of 1.0 m or less is classified into the “short” category. A distance from 1.0 m to 10.0 m is classified into the “middle” category. A distance of 10.0 m or more is classified into the “long” category. As in the case of temperature, the result of classification is expressed by setting a predetermined flag to the respective blocks.

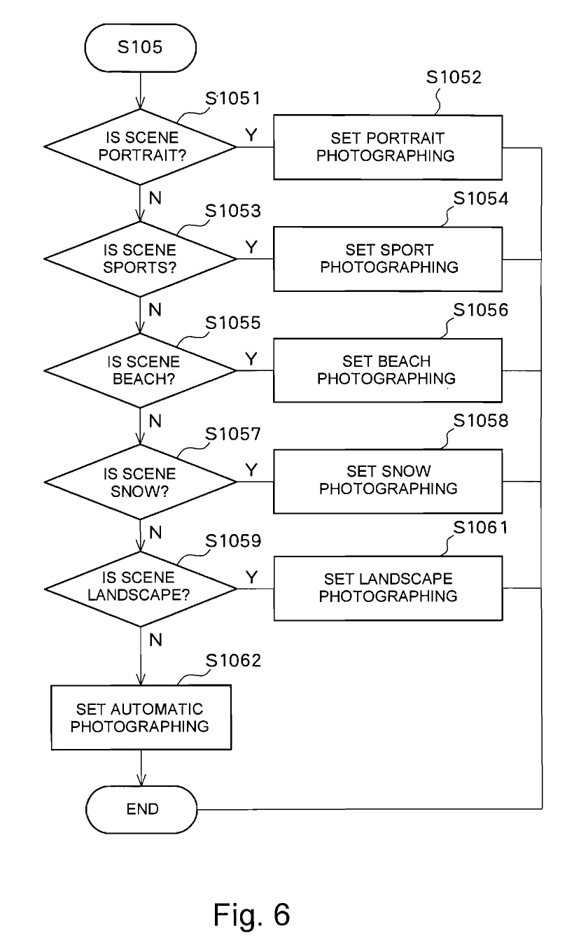

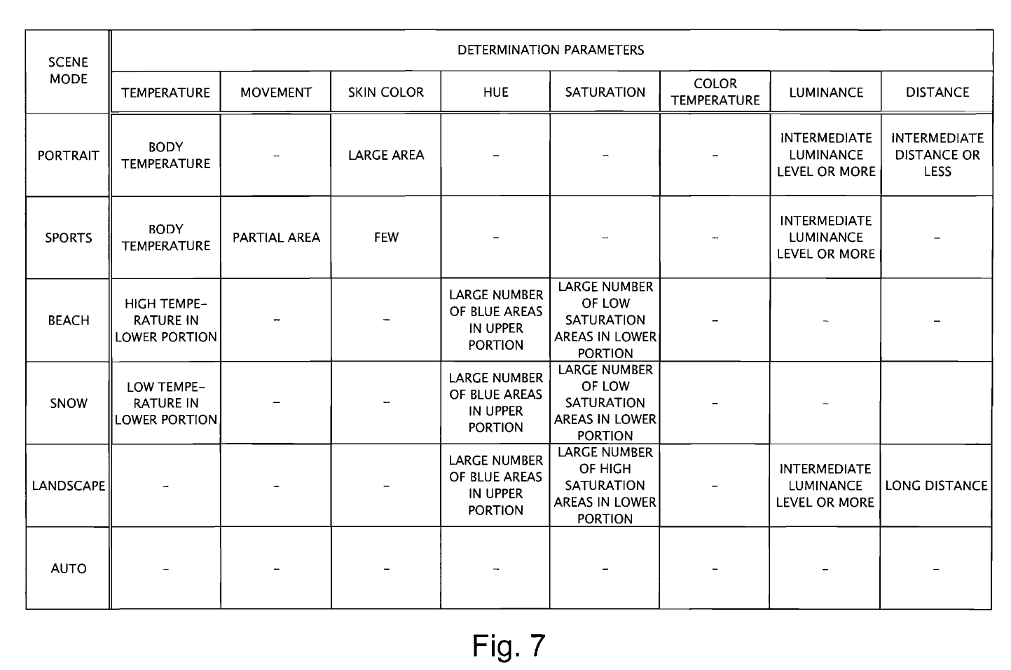

FIG. 6 shows a detailed flowchart of processing pertaining to S105 shown in FIG. 2; namely, processing for determining a scene. FIG. 7 shows a table used for determining a scene. The table shown in FIG. 7 is stored in advance as a firmware in ROM or the like. The temperature characteristic output from the temperature-based information characteristic extraction circuit 24 and the image characteristics, such as hue and saturation, output from the image characteristic extraction circuit 18 are input to the scene determination circuit 26, where a scene is determined on the basis of these characteristics.

First, the scene determination circuit 26 determines whether or not the field is a portrait (Portrait) (S1051). As shown in FIG. 7, the flags of the respective blocks are ascertained. When there is a block having a large skin-color area, a middle luminance level or more, a middle distance, and a body temperature, the photographic scene is determined to be a portrait (S1052).

When the scene is not a portrait, a determination is then made as to whether or not the scene is a sports scene (Sports) (S1053). As shown in FIG. 7, when there is a block having a partial movement area, a small area of the skin-color region, a low frequency of appearance of the skin-color region, an intermediate luminance level or more, and a body temperature, the scene is determined to be a sports scene (S1054).

When the scene is not a sports scene, a determination is then made as to whether or not the scene is a beach scene (Beach) (S1055). As shown in FIG. 7, where an upper region (an upper block) of the field has a high frequency of appearance of a blue hue area and a lower region (a lower block) has a high frequency of appearance of a low saturation area and has a high temperature, the scene is determined to be a beach (S1056). The term “upper region” employed herein signifies a vertically-upward direction (the direction toward the top) in the field or an image, and the term “lower region” employed herein signifies a vertically-downward direction (the direction toward the bottom) in the field or the image.

When the scene is not a beach, a determination is made as to whether or not the scene is snow (Snow) (S1057). As shown in FIG. 7, when the upper region of the field has a high frequency of appearance of the blue hue area; the lower region has a high frequency of appearance of a low saturation area; and the lower region has a low temperature, the scene is determined to be snow (S1058).

When the scene is not snow, a determination is made as to whether or not the scene is a landscape (Landscape) (S1059). As shown in FIG. 7, when the upper region has a great frequency of appearance of a blue hue area, and the lower region has a high frequency of appearance of a high saturation area, a long distance, and the intermediate luminance level or higher, the scene is determined to be a landscape (S1061).

When the scene corresponds to none of these categories, the scene is determined to be a normal photographic scene which does not specify a scene (an automatic photographing mode) (S1062).

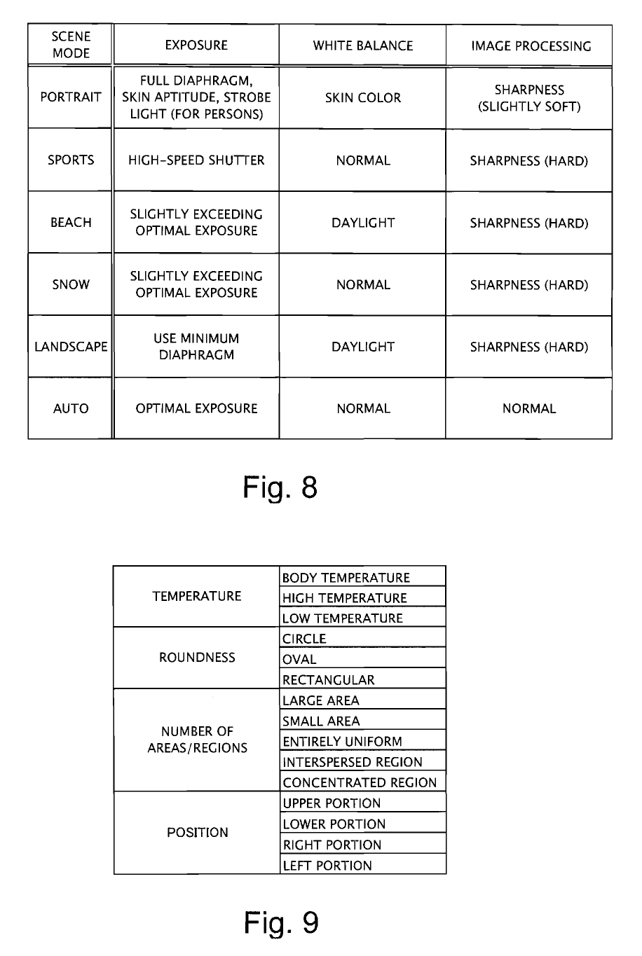

FIG. 8 shows processing pertaining to step S106 shown in FIG. 2; namely, processing for changing photographing conditions/image parameters on a per-scene basis in accordance with the result of determination of the scene.

When the determined scene is a portrait, the CPU 28 sets aperture to maximum in order to make the depth of a field shallow to thus throw a background out of focus. Further, shutter speed is set in order to make the skin-color area appropriately exposed. Further, a strobe light is fired in order to prevent shading of the skin of a person. The quantity of strobe light is limited to such an extent that solid white does not appear on the person. Further, sharpness (edge processing) of a captured still image is set to a soft level.

When the determined scene is a sports scene, the CPU 28 sets the shutter speed as fast as possible in order to prevent movement of the object. Further, sharpness of a captured still image is set to a high level.

In the case where the determined scene is a beach, when the CPU 28 performs appropriate exposure control, an image having the tendency of underexposure is acquired. For this reason, the shutter speed, ISO sensitivity, and the diaphragm are set such that exposure which is greater than appropriate exposure is obtained. In relation to the image captured as a still image, white balance is set to a daylight level, and sharpness is set to a high level.

In the case where the determined scene is snow, when the CPU 28 performs appropriate exposure control, an image having the tendency of underexposure is acquired. For this reason, the shutter speed, the ISO sensitivity, and the diaphragm are set such that exposure which is greater than appropriate exposure is obtained. White balance is set to a normal level, and sharpness is set to a high level.

In the case where the determined scene is a landscape, the depth of the field is set to a high level, and exposure control for reducing the aperture as low as possible is performed with a view toward capturing subjects from a close subject to a landscape such as mountains in the distance, or the like. White balance is set to a daylight level, and sharpness is set to a high level.

Meanwhile, when the scene is determined to be none of the categories but a normal photographic scene, the CPU 28 controls the overall image such that appropriate exposure is achieved. Sharpness is set to a normal level.

As mentioned above, in the present embodiment the scene is determined in consideration of the temperature of the field, and elaborate control is performed for each determined scene, so that a high-quality image appropriate for the field can be readily obtained.

The temperature sensor 8 of the present embodiment detects the temperature of the field by utilization of the bifurcated light obtained from the light having entered the optical system 10. However, the essential requirement is to be able to detect the temperature of an area falling within the angle of field, which includes the angle of view corresponding to the field obtained by the optical system 10, independently of the optical system 10. When having determined the photographic scene, the CPU 28 may display the result of determination on the LCD 38 to thus report the result to the user. For instance, when a scene has been determined to be a beach scene, a message of “beach scene” is displayed, or an icon signifying a beach is displayed or the like.

### Second Embodiment

In the first embodiment, the image region of the field is divided into a plurality of blocks and the respective blocks are classified into the “body temperature” category, the “high temperature” category, and the “low temperature” category as the characteristic of the temperature detected by the temperature sensor 8. However, the characteristic of the temperature may be detected in a more elaborate manner.

FIG. 9 shows temperature characteristics of the present embodiment. The temperature is not only classified into the “body temperature” category, the “high temperature” category, and the “low temperature” category, but also further characterized by roundness, the number of areas/regions, and positions. Roundness is classified into any of the “circle” category, the “oval” category, and the “rectangular” category. The number of areas or regions is classified into any of a “large area” category, a “small area” category, an “entirely uniform” category, an “interspersed region” category, and a “concentrated region” category. Further, position is classified into any of an “upper portion” category, a “lower portion” category, a “right portion” category, and a “left portion” category. For instance, a temperature is classified into the “body temperature,” the “large area”, the “concentrated region,” the “lower portion of an image,” and the like.

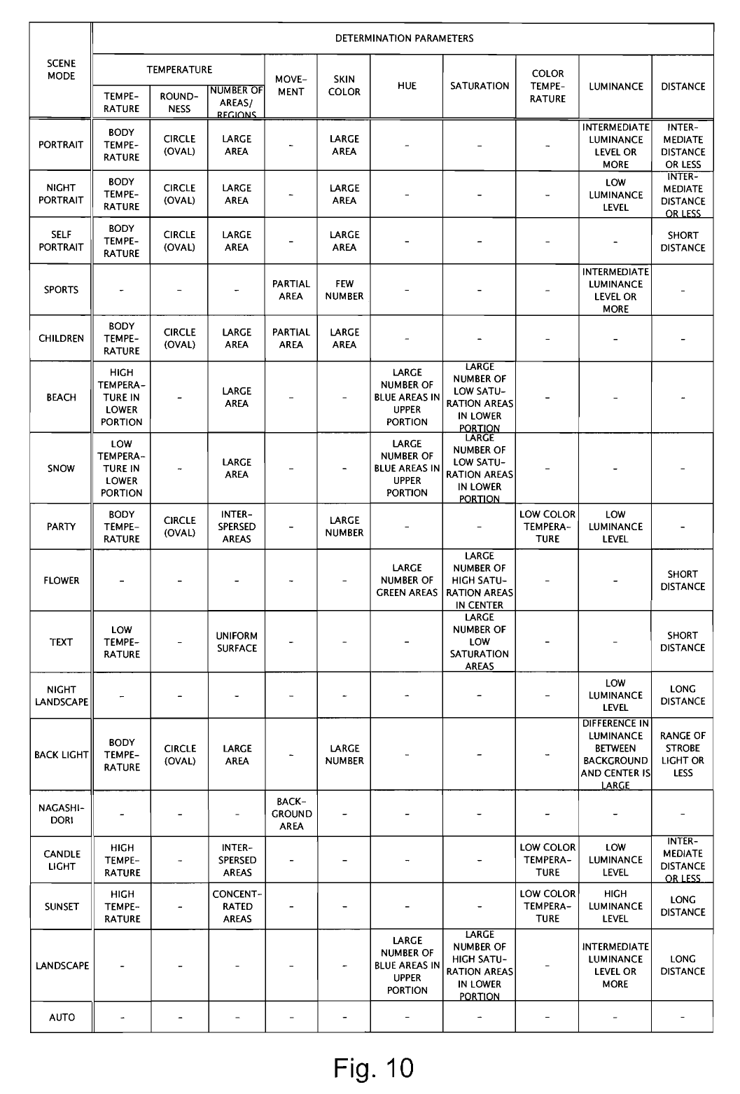

FIG. 10 shows a table used for determination processing performed by the scene determination circuit 26. Roundness and the number of areas/regions as well as a mere temperature are used as temperature characteristics. When a portrait has the temperature classified into the “body temperature” category, the roundness classified into the “oval” category, the number of areas/regions classified into the “large area” category, the skin color classified into the “large area” category, the luminance classified into the “low luminance” category, and the distance classified into the “middle” category, the scene determination circuit 26 determines the scene to be a night-view portrait. Further, when a portrait has the temperature classified into the “body temperature” category, the roundness classified into the “oval” category, the number of areas/regions classified into the “large area” category, the skin color classified into the “large area” category, and the distance classified into the “short” category, the scene determination circuit 26 determines the scene to be a self-portrait. Moreover, when a portrait has the temperature classified into the “body temperature” category, the roundness classified into the “circle” or “oval” category, the number of areas/regions classified into the “large area” category, the movement classified into the “partial region” category, and the skin color classified into the “large area” category, the scene determination circuit 26 determines the scene to be a child portrait (Children). When a portrait has the temperature classified into the “body temperature” category, the roundness classified into the “circle” or “oval” category, the number of areas/regions classified into the “interspersed region” category, the skin color classified into the “high frequency of appearance” category, and the color temperature classified into the “low color temperature” category, the scene determination circuit 26 determines the scene to be a party (Party).

Even when a scene is anything other than a portrait but has the hue classified into a “large number of green regions” category, the saturation classified into a “large area of high saturation in the center” category, and the distance classified into the “short” category, the scene is determined to be flowers (Flower).

When a scene has the temperature classified into the “low temperature” category, the number of areas/regions classified into a “uniform surface” category, the saturation classified into a “large number of areas of low saturation” category, and the distance classified into the “short” category, the scene is determined to be a document (Text).

Further, when a scene has the luminance classified into the “low luminance” category and the distance classified into the “long” category, the scene is determined to be a night landscape (Night Landscape). When a scene has the temperature classified into the “body temperature,” the roundness classified into the “circle or oval” category, the number of areas/regions classified into the “large area” category, the skin color classified into the “large number” category, the luminance classified into a “large difference of luminance between a background and the center” category, and the distance classified into a “range of strobe light of less” category, the scene is determined to be backlight. When movement is classified into the “background” category, the action is determined to be a panning shot (Nagashidori). Further, when a scene has the temperature classified into the “high temperature” category, the number of areas/regions classified into the “interspersed region” category, the color temperature classified into the “low color temperature” category, the luminance classified into the “low luminance” category, and the distance classified into the “intermediate distance or less” category, the scene is determined to be candle light (Candle Light). When a scene has the temperature classified into the “high temperature” category, the number of areas/regions classified into the “concentrated area” category, the color temperature classified into the “low color temperature” category, and the distance classified into the “long” category, the scene is determined to be a sunset (Sunset).

As above, determination of a scene with higher accuracy becomes possible by means of characterizing a temperature more elaborately. Needless to say, the position of the temperature may further be adopted in FIG. 10. When the position of the body temperature is in a lower portion, the scene is determined to be a child or the like.

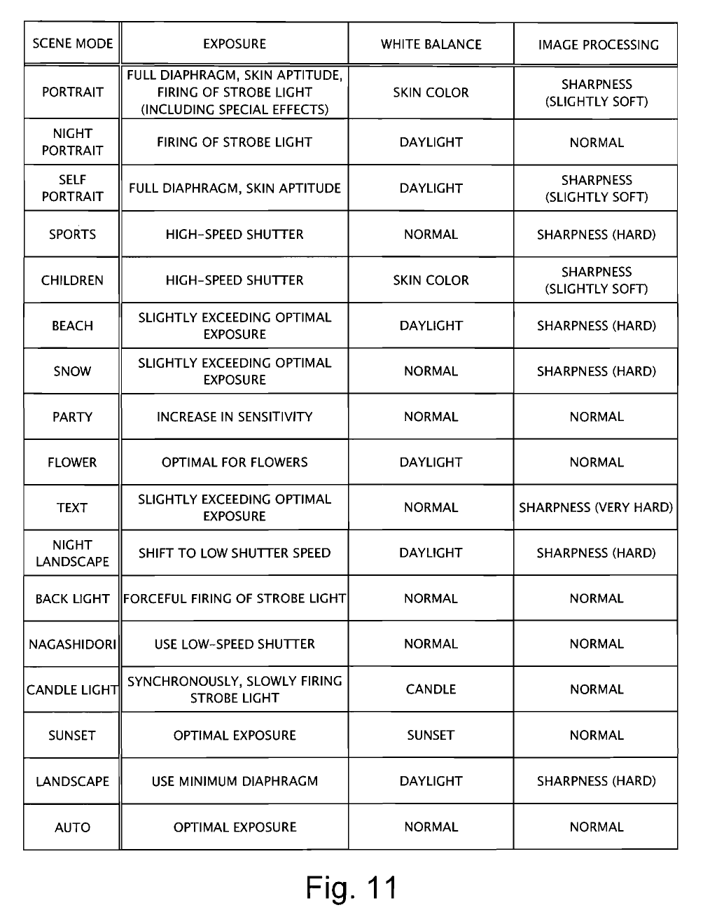

FIG. 11 shows processing for changing photographing conditions/image parameters for each determined scene in the present embodiment. When the scene has been determined to be a night portrait, the CPU 28 controls exposure by means of firing a strobe light. When the scene has been determined to be a self-portrait, diaphragm is set to full, and sharpness is set to a soft level. When the scene has been determined to be a child, the shutter speed is set to a high-speed shutter speed, and sharpness is set to a hard level. When the scene has been determined to be a text, exposure is controlled to such an extent that exposure, which exceeds appropriate exposure, is obtained, and sharpness is set to a hard level. The same also applies to any counterparts in the following descriptions.

As stated above, the accuracy of determination of a scene can be enhanced by means of increasing the sensitivity of the temperature sensor 8 and detecting the temperature characteristics with high accuracy. In the present embodiment, since the area of a body temperature can be detected with high accuracy, the area of a person can be brought into focus in conjunction with an autofocus mechanism.

Even in Japanese Laid-Open Patent Publication No. Hei-8-136971 of the related art, the body temperature area is detected by means of an infrared camera, and the thus-detected area is brought into focus. In the present embodiment, however, attention must be paid to the fact that a determination is rendered by means of not only a mere body temperature but also taking into consideration roundness and the number of areas/regions.

### Third Embodiment

Although in the first and second embodiments the temperature of the field is detected by means of uniform sensitivity from a high temperature to a low temperature, only a specific temperature may also be selectively detected. For instance, the temperature of only the sun, only a body temperature, the temperature of only sky, the temperature of only ice or snow, or the like, is detected. FIG. 12 shows a case where only a body temperature of an image of the field is selectively detected. Among the plurality of blocks, only the block having the body temperature is selected as an object of processing. The other blocks are not taken as an object. A scene is determined on the basis of the block that has been taken as an object of processing, and photographing conditions and parameters of image processing are adjusted.

Although the embodiments of the present invention have been described thus far, the present invention is not limited to the embodiments but may also be materialized in the form of other embodiments. A subject can be extracted even with low luminance of the field (or, in the worst case, even in a dark state) by utilization of temperature detection to focus control, so that a focus can be achieved without fail. Moreover, so long as a pre-flash light is fired during focusing operation, exposure can also be detected. Accordingly, more reliable photographing can also be possible even in a dark condition.

For instance, when the area of body temperature has been detected and the chance of a person being present in the field has been determined to be high from roundness, the number of areas/regions, and the position of the body temperature, at least two characteristic points, such as eyes, nose, mouth, and ears, are extracted from the region of the person. When the thus-extracted characteristics coincide with the characteristics of a human face, the scene may be determined to be a portrait.

The edge component of a temperature may be extracted while the focus is being actuated, and a peak may further be detected from the edge components, and the focus may be actuated to an optimal focus position with regard to the nearest subject. For instance, a body temperature region is detected, and a peak is detected from edge components of the body temperature region. The focus is moved to the optimal focus position with regard to the subject in the body temperature region.

Further, the temperature of the field is acquired while the focus is being actuated, and the image-capturing element 12 acquires an image limited to such a gain increase that the AF evaluation is not affected. Data which involve little noise and whose peak is easy to detect may be acquired on the basis of temperature data and image data.

Moreover, a person may be detected from the temperature of the field, and data pertaining to a pre-fired strobe light reflected from the detected person may be acquired, whereby the quantity of strobe light may also be controlled.

### PARTS LIST

6 analog-to-digital circuit
7 analog-to-digital circuit
8 temperature sensor
9 AF sensor
10 optical system
11 half mirror
12 image-capturing element (S103)
14 AF sensor processing circuit
16 image-capturing element drive circuit
18 extraction circuit
22 temperature sensor control circuit
24 extraction circuit
26 determination circuit
28 CPU
30 shutter control circuit
32 diaphragm motor control circuit
34 focus motor control circuit
36 built in memory
38 color LCD
S101 temperature information
S102 characteristic of temperature
S104 characteristic of image
S105 photographic scene of the field
S106 determined scene
S1021 plurality of blocks
S1022 body temperature
S1023 body temperature
S1024 high temperature
S1025 high temperature
S1026 low temperature
S1027 classification processing
S1051 portrait determination scene
S1052 portrait scene
S1053 sports determination scene
S1054 sports scene
S1055 beach determination scene
S1056 beach scene
S1057 snow determination scene
S1058 snow scene
S1059 landscape determination scene
S1061 landscape scene
S1062 normal photographic scene
T temperature
TL upper portion of screen
TH lower portion of screen
T1 threshold temperature
T2 threshold temperature

What is claimed is:

1. An image-capturing apparatus comprising:
temperature detection means for detecting a temperature of a field;
image acquisition means for acquiring an image signal pertaining to the field;
image-processing means for detecting image characteristic information, such as a hue, saturation, luminance, a distance, movements, and the like, from the image signal obtained by the image acquisition means; and
determination means for determining which one of a plurality of photographic scenes corresponds to the field on the basis of a combination of the temperature information about the field detected by the temperature detection means and the image characteristic information detected by the image-processing means.

2. The image-capturing apparatus according to claim 1, wherein at least one of the image characteristic information and the temperature information is detected by means of dividing an image of the field into a plurality of areas and analyzing information about individual areas.

3. The image-capturing apparatus according to claim 1, further comprising
adjustment means for adjusting photographing conditions of the image acquired by the image acquisition means, such as exposure, a white balance, focus adjustment, the quantity of flash light, and the like, according to a photographic scene determined by the determination means.

4. The image-capturing apparatus according to claim 1, further comprising
classification means for classifying the temperature detected by the temperature detection means into temperature distributions determined by use of a plurality of preset temperatures, wherein
the preset temperature includes at least a temperature by means of which the temperature of a person can be classified and another temperature by means of which a temperature can be determined to be higher or lower than that temperature; and
the determination means determines which one of the plurality of photographic scenes corresponds to the field, on the basis of the temperature determined by the classification means.

5. The image-capturing apparatus according to claim 4, wherein the classification means classifies the temperature detected by the temperature detection means by means of at least one of the shape of the temperature distribution, the area of the temperature distribution, and the position of a view angle of the temperature distribution.

6. The image-capturing apparatus according to claim 4, wherein the plurality of photographic scenes include at least beach scene and a snow scene; and
the determination means determines the field to be a beach scene when the temperature detected by the temperature detection means is high in a vertically-downward area in the image and a blue hue area appears in a vertically-upward area in the image, and determines the field to be a snow scene when the temperature detected by the temperature detection means is low in the vertically-downward area in the image and the blue hue area appears in the vertically-upward area in the image.

7. The image-capturing apparatus according to claim 4, wherein the plurality of photographic scenes include at least beach scene and a snow scene; and
the determination means determines the field to be the beach scene when the temperature detected by the temperature detection means is high in a vertically-downward area in the image and low saturation is achieved in the vertically-downward area in the image, and determines the field to be the snow scene when the temperature detected by the temperature detection means is low in the vertically-downward area in the image and low saturation is achieved in the vertically-downward area in the image.

8. The image-capturing apparatus according to claim 5, wherein, when the temperature detected by the temperature detection means corresponds to a body temperature, the determination means determines a scene to be a portrait scene on the basis of at least any of the geometry of the temperature distribution, the area of the temperature distribution, and the position of the view angle of the temperature distribution.

9. The image-capturing apparatus according to any one of claim 1, further comprising:
reporting means for reporting the photographic scene determined by the determination means to the user.
